(19) United States
(12) Patent Application Publication
(10) Pub. No.: US 2010/0090315 A1
(43) Pub. Date: Apr. 15, 2010

(54) FILM FORMING METHOD, FILM FORMING APPARATUS, STORAGE MEDIUM AND SEMICONDUCTOR DEVICE

(75) Inventor: Masahiro Horigome, Nirasaki-shi (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/517,160

(22) PCT Filed: Nov. 30, 2007
(86) PCT No.: PCT/JP2007/073227

§ 371 Date: Jun. 1, 2009

(30) Foreign Application Priority Data
Dec. 1, 2006 (JP) 2006-326041

(51) Int. Cl. H01L 23/48; H01L 21/31; C23C 16/00

(52) U.S. Cl. 257/618; 438/778; 118/723 AN; 257/E21.24; 257/E23.011

(57) ABSTRACT

Provided is a film forming method comprising: placing a substrate on a loading portion inside a processing chamber; supplying a gas for generating plasma, which is excited by microwaves, into the processing chamber; evacuating an inside of the processing chamber; supplying a C₅F₈ gas into the processing chamber; supplying microwaves into the processing chamber from a planar antenna member, which is disposed on an upper part of the processing chamber to face the loading portion and in which a plurality of slots are formed along a circumferential direction, and plasmatizing the gas inside the processing chamber; forming a fluorine-added carbon film on the substrate by the plasmatized gas; and applying a biasing high frequency power to the loading portion while forming the fluorine-added carbon film on the substrate so that the biasing high frequency power of 0.32 W/cm² or less is applied on the substrate per unit area.

### CROSS-REFERENCE TO RELATED PATENT APPLICATION

This application claims the benefit of Japanese Patent Application No. 2006-326041 filed on Dec. 1, 2006, in the Japan Patent Office, the disclosure of which is incorporated herein their entirety by reference.

### TECHNICAL FIELD

The present invention relates to technology for forming a fluorine-added carbon film by using plasma.

### BACKGROUND ART

A multilayer wiring structure is employed so as to implement highly-integrated semiconductor devices. However, as semiconductor devices are fine and highly integrated, delay of an electrical signal (wiring delay) that passes through wiring disturbs a high-speed operation of a device. Thus, as a demand for reducing wiring delay, an interlayer insulating film by which layers are insulated from each other, needs to have low dielectric constant.

From the demand, as an interlayer insulating film, a porous silicon, carbon, oxygen and hydrogen-containing film (SiCOH film) having relative permittivity of about 2.7 and having a sufficient mechanical strength is focused. However, the present inventors have considered to employ a fluorine-added carbon film (fluorocarbon film) which has lower relative permittivity than that of the SiCOH film and is a compound of carbon (C) and fluorine (F).

The fluorine-added carbon film is a very effective film for obtaining low relative permittivity of 2.5 or less, for example, when the type of a raw material gas is selected. Meanwhile, the interlayer insulating film needs to have a small leak current property, to have a high elastic modulus so as to prevent peeling of the film when stress is applied during or after a process of fabricating a semiconductor device, and to have a large mechanical strength so as to prevent the breaking of the film due to a chemical mechanical polishing (CMP) process that is performed after a metal wiring such as copper (Cu) is buried.

In addition, a coefficient of thermal expansion (CTE) of the interlayer insulating film needs to be suppressed to be low, because a heat treatment process or cooling process is performed as a semiconductor device manufacturing process. When the CTE of the interlayer insulating film is large, the interlayer insulating film and a wiring material expand or contract each other during the heat treatment process or the cooling process so that peeling of the film or wiring disconnection may occur.

By the way, several types of gases are known as a raw material gas of a fluorine-added carbon film. Among the gases, a C₅F₈ gas is advantageous in that its decomposition product is subject to form a steric structure and as a result, C—F is tightly bonded and thus, an interlayer insulating film having low relative dielectric constant, a small leak current and a large film strength or a large stress-resistant property is obtained. Japanese Laid-open Patent Publication No. hei 10-144675 (FIG. 19, Paragraph [0046]) discloses a plasma film forming apparatus using microwaves as a plasma film forming apparatus for plasmatizing a C₅F₈ gas. In the above publication, technology in which the electron temperature of plasma is reduced so that excessive decomposition of a material is suppressed and thereby, a fluorine-added carbon film which has an original composition or structure of the material can be obtained, is disclosed.

Even though the quality of the fluorine-added carbon film is being improved, the mechanical strength of the fluorine-added carbon film, such as an elastic modulus or a hardness, is very lower than the mechanical strength of a silicon oxide film. Due to this drawback, the fluorine-added carbon film is not easily put as the interlayer insulating film to practical use. In addition, in order to put the fluorine-added carbon film as the interlayer insulating film to practical use, a leak current of the fluorine-added carbon film may be greatly reduced, and a CTE thereof may be greatly reduced.

In Japanese Laid-open Patent Publication No. hei 10-144675 (FIG. 19, Paragraph [0046]), experimental data in which a biasing power of 500 W or more is applied on an 8-inch wafer and a burying characteristic of a fluorine-added carbon film between aluminum wirings is investigated, is disclosed. However, a plasma film forming apparatus disclosed in Japanese Laid-open Patent Publication No. hei 10-144675 uses electron cyclotron resonance, and the electron temperature of plasma is so high that the fluorine-added carbon film is very weak and thus, the above-mentioned problem cannot be solved.

### DISCLOSURE OF THE INVENTION

The present invention provides technology for obtaining a good fluorine-added carbon film having a large elastic modulus and a large mechanical strength.

The present invention also provides a semiconductor device including the good fluorine-added carbon film.

### TECHNICAL SOLUTION

According to an aspect of the present invention, there is provided a film forming method comprising: placing a substrate on a loading portion inside a processing chamber; supplying a gas for generating plasma, which is excited by microwaves, into the processing chamber; evacuating an inside of the processing chamber; supplying a C₅F₈ gas into the processing chamber; supplying microwaves into the processing chamber from a planar antenna member, which is disposed on an upper part of the processing chamber to face the loading portion and in which a plurality of slots are formed along a circumferential direction, and plasmatizing the gas inside the processing chamber; forming a fluorine-added carbon film on the substrate by the plasmatized gas; and applying a biasing high frequency power to the loading portion while forming the fluorine-added carbon film on the substrate so that the biasing high frequency power of 0.32 W/cm² or less is applied on the substrate per unit area.

The C₅F₈ gas may include an octafluorocyclopentene gas, an octafluoropentyne gas or an octafluoropentadiene gas.

The fluorine-added carbon film may preferably be an insulating film included in a semiconductor device.

According to another aspect of the present invention, there is provided a film forming apparatus comprising: a processing chamber having an air tight structure; a loading portion, which is formed inside the processing chamber and on which a substrate is placed; a waveguide situated lateral to the processing chamber and guiding microwaves to one end of the waveguide; a planar antenna member, which is disposed on the processing chamber and is connected to one end of the waveguide to face the loading portion and in which a plurality of slots for supplying microwaves introduced by the waveguide into the processing chamber are formed along a circumferential direction; a plasma gas supplying means disposed on the processing chamber and supplying a gas for generating plasma excited by the microwaves into the processing chamber; a C₅F₈ gas supplying means disposed on the processing chamber separately from the plasma gas supplying means and supplying a C₅F₈ gas into the processing chamber; an exhaust means for evacuating an inside of the processing chamber; and a high frequency power applying means for applying a biasing high frequency power to the loading portion so that the biasing high frequency power of 0.32 W/cm² or less is applied on the substrate per unit area, wherein the gas supplied into the processing chamber is plasmatized by microwaves from the planar antenna member, and a fluorine-added carbon film is formed on the substrate by the plasmatized gas.

The film forming apparatus may further include a control means for controlling the plasma gas supplying means, the C₅F₈ gas supplying means, the planar antenna member, and the high frequency power applying means by receiving outputs of the control commands.

One slot and the other slot formed in the planar antenna member may be disposed to form an approximately T shape.

According to another aspect of the present invention, there is provided a storage medium in which a computer program for executing a film forming method is stored on a computer, wherein the film forming method comprises: placing a substrate on a loading portion inside a processing chamber; supplying a gas for generating plasma, which is excited by microwaves, into the processing chamber; evacuating an inside of the processing chamber; supplying a C₅F₈ gas into the processing chamber; supplying microwaves into the processing chamber from a planar antenna member, which is disposed on an upper part of the processing chamber to face the loading portion and in which a plurality of slots are formed along a circumferential direction, and plasmatizing the gas inside the processing chamber; forming a fluorine-added carbon film on the substrate by the plasmatized gas; and applying a biasing high frequency power to the loading portion while forming the fluorine-added carbon film on the substrate so that the biasing high frequency power of 0.32 W/cm² or less is applied on the substrate per unit area.

According to another aspect of the present invention, there is provided a semiconductor device comprising an insulating film, wherein the insulating film is comprised of a fluorine-added carbon film, which is formed by a film forming method including: placing a substrate on a loading portion inside a processing chamber; supplying a gas for generating plasma, which is excited by microwaves, into the processing chamber; evacuating an inside of the processing chamber; supplying a C₅F₈ gas into the processing chamber; supplying microwaves into the processing chamber from a planar antenna member, which is disposed on an upper part of the processing chamber to face the loading portion and in which a plurality of slots are formed along a circumferential direction, and plasmatizing the gas inside the processing chamber; forming a fluorine-added carbon film on the substrate by the plasmatized gas; and applying a biasing high frequency power to the loading portion while forming the fluorine-added carbon film on the substrate so that the biasing high frequency power of 0.32 W/cm² or less is applied on the substrate per unit area.

According to the present invention, while an apparatus for supplying microwaves into a processing chamber from a planar antenna member and generating plasma having a low electron temperature near the surface of a substrate is used, an appropriate biasing power is applied on the substrate during film forming when a fluorine-added carbon film is formed by using a C₅F₈ gas as a processing gas, and thus, as clarified by examples that will be described later, a fluorine-added carbon film having a large elastic modulus and large hardness can be obtained.

### BRIEF DESCRIPTION OF THE DRAWINGS

FIG. 1 is a cross-sectional view of a semiconductor device according to an embodiment of the present invention;

FIG. 2 is a longitudinal side sectional view of a plasma film forming apparatus according to an embodiment of the present invention;

FIG. 3 is a plan view of a second gas supplying portion used in the plasma film forming apparatus;

FIG. 4 is a perspective view of a part of a cross-section of an antenna member used in the plasma film forming apparatus;

FIG. 5 illustrates a C₅F₈ gas used in an embodiment of the present invention;

FIG. 6 is a schematic view of a state of a CF film formed;

FIG. 7 illustrates a process of fabricating a semiconductor device including a CF film according to an embodiment of the present invention;

FIG. 8 is a schematic plan view of an apparatus for fabricating the semiconductor device of FIG. 7, according to an embodiment of the present invention;

FIG. 9 illustrates target positions on which X-ray photoelectron spectroscopy (XPS) analysis are to be performed, of a fluorine-added carbon film, according to examples of the present invention;

FIG. 10 illustrates results of XPS analysis of the fluorine-added carbon film according to examples of the present invention;

FIG. 11 illustrates dependency of a biasing power on a leak current of the fluorine-added carbon film;

FIG. 12 illustrates dependency of the biasing power on a hardness of the fluorine-added carbon film;

FIG. 13 illustrates dependency of the biasing power on a Young's modulus of the fluorine-added carbon film;

FIG. 14 illustrates dependency of the biasing power on a film forming speed of the fluorine-added carbon film; and

FIG. 15 illustrates dependency of the biasing power on relative permittivity of the fluorine-added carbon film.

### BEST MODE FOR CARRYING OUT THE INVENTION

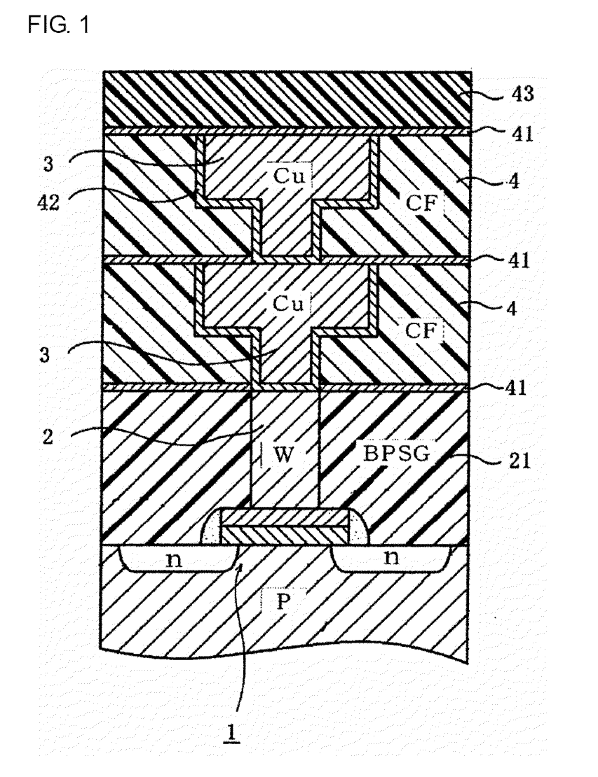

Before describing embodiments of a film forming method according to the present invention, an example in which a fluorine-added carbon film (hereinafter, a CF film) that is obtained by the film forming method is used, is shown in FIG. 1. FIG. 1 is an example of a semiconductor device in which the CF film is used as an interlayer insulating film, according to an embodiment of the present invention. Reference numerals 1, 2, and 21 denote a metal-oxide-semiconductor (MOS) transistor, a wiring composed of tungsten (W) connected to a gate electrode, and a boron phosphosilicate glass (BPSG) film, respectively. Interlayer insulating films 4 each being the CF film according to the present invention and having buried therein a wiring layer 3 composed of copper (Cu), for example, are laminated in multilayer on the BPSG film 21 (in FIG. 1, two layered structure is illustrated for explanatory conveniences). In addition, reference numeral 41 denotes a hard mask composed of silicon nitride, for example, and reference numeral 42 denotes a barrier layer composed of titanium nitride or tantalum nitride, for example, for preventing the diffusion of a wiring metal, and reference numeral 43 denotes a protective film. The wiring layer 3 is formed by a recent dual damascene method in such a way that the CF film 4 is blanket formed on the hard mask 41 and then, a recess portion such as a groove or hole for forming the wiring layer 3 is formed by etching, and copper (Cu) as a wiring material is buried within the recess portion by physical vapor deposition (PVD) or plating.

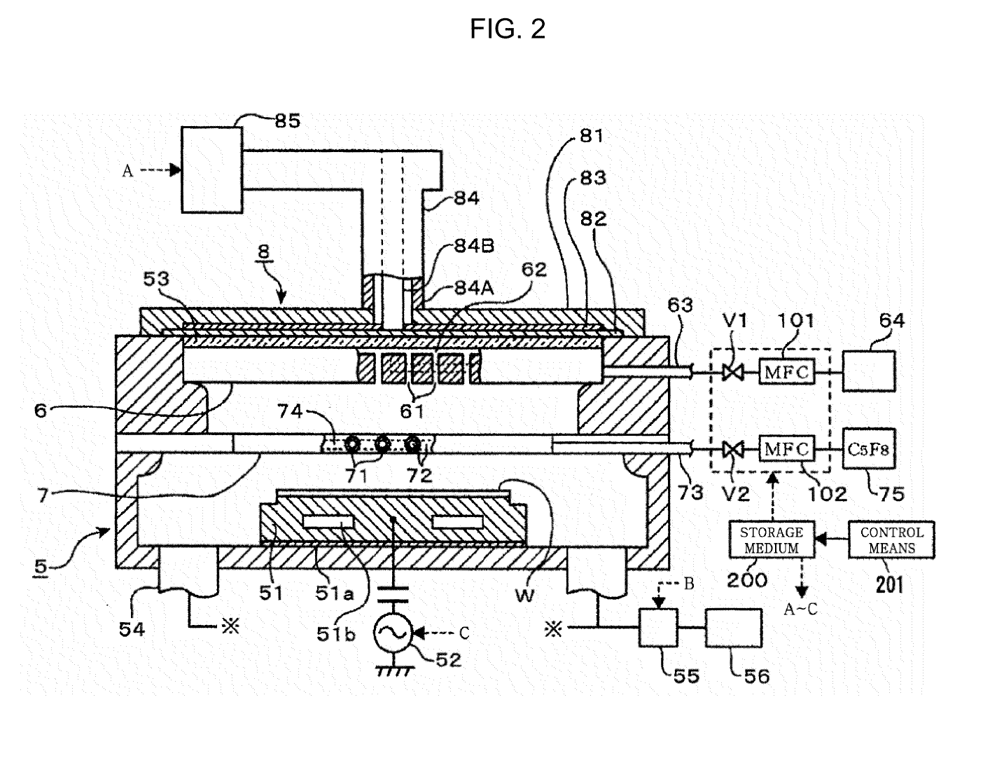

Subsequently, embodiments of a film forming method and a plasma film forming apparatus used in performing the film forming method according to the present invention will now be described with reference to FIGS. 2 through 4. The plasma film forming apparatus is a chemical vapor deposition (CVD) apparatus that generates plasma by using a radial line slot antenna. Reference numeral 5 of FIG. 2 is a processing chamber (vacuum chamber) in the form of a case, for example, and a sidewall or bottom part of the processing chamber 5 is composed of a conductor, for example, aluminum-added stainless steel, and a protective film composed of aluminum oxide is formed on an inner wall surface of the processing chamber 5.

A loading table 51 as a loading portion on which a substrate, for example, a wafer W is placed, is disposed nearly in the middle of the processing chamber 5 through an insulating material 51a. The loading table 51 is composed of aluminum nitride (AlN) or aluminum oxide (Al₂O₃), for example, and a cooling jacket 51b through which a cooling medium flows is formed inside the loading table 51, and a heater (not shown) is disposed to constitute a temperature controller together with the cooling jacket 51b. A loading surface of the loading table 51 is formed of an electrostatic chuck. In addition, a power supply source 52 of a biasing high frequency power having a frequency range from 800 KHz, for example, to 2 MHz, in which ions follow, is connected to the loading table 51.

A ceiling part of the processing chamber 5 is open, and a first gas supplying portion (plasma gas supplying means) 6 having an approximately circular shape in a plane, for example, is sealed with the ceiling part of the processing chamber 5 through a seal member (not shown) such as an O-ring, so as to face the loading table 51. The first gas supplying portion 6 is composed of aluminum oxide, for example, and a gas flow path 62 is formed in a surface that faces the loading table 51 and communicates with a first end of a gas supplying hole 61, and a first end of a first gas supplying path 63 is connected to the gas flow path 62. Meanwhile, a supply source 64 of a rare gas such as an argon (Ar) gas or a krypton (Kr) gas for generating plasma (plasma gas), is connected to a second end of the first gas supplying path 63, and the plasma gas is supplied to the gas flow path 62 through the first gas supplying path 63 and is uniformly supplied to a space below the first gas supplying portion 6 through the gas supplying hole 61.

In the present embodiment, a means for supplying the processing chamber 5 with the gas for generating plasma is provided by the supply source 64, the first gas supplying path 63, and the first gas supplying portion 6.

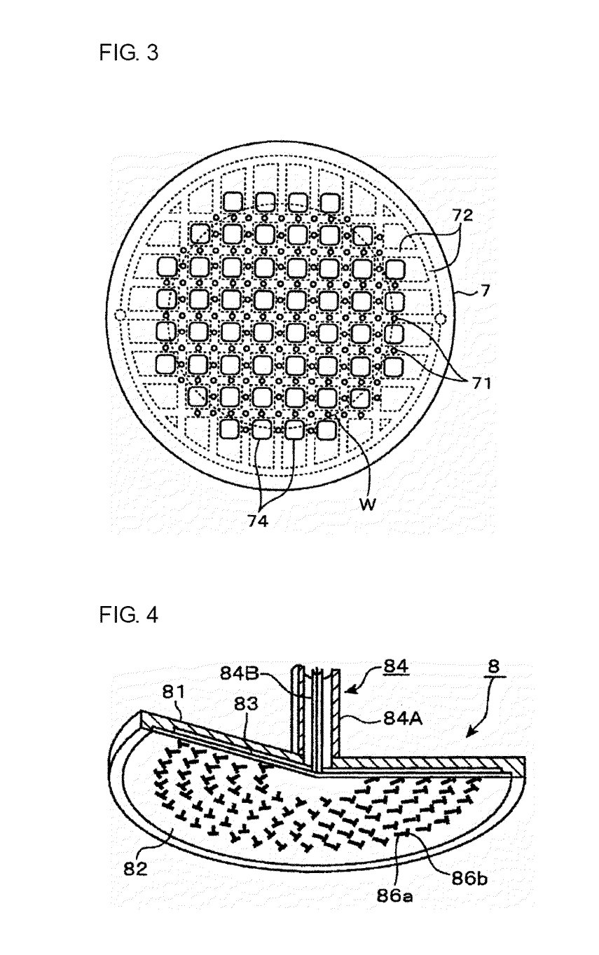

In addition, the processing chamber 5 includes a second gas supplying portion (C₅F₈ gas supplying means) 7 that has an approximately circular shape in a plane, for example, and that is disposed between the loading table 51 and the first gas supplying portion 6 to partition between the loading table 51 and the first gas supplying portion 6, for example. The second gas supplying portion 7 is composed of a conductor such as aluminum alloy including magnesium (Mg) or aluminum-added stainless steel, for example. A plurality of second gas supplying holes 71 are formed in a surface that faces the loading table 51. A gas flow path 72 having a lattice shape that communicates with first ends of the second gas supplying holes 71 is disposed inside the second gas supplying portion 7, as illustrated in FIG. 3, for example, and a first end of a second gas supplying path 73 is connected to the gas flow path 72. In addition, a plurality of openings 74 are formed in the second gas supplying portion 7 to penetrate the second gas supplying portion 7. The openings 74 allow plasma or a raw material gas in the plasma to pass through the space below the second gas supplying portion 7 and are formed between adjacent portions of the gas flow path 72.

Here, the second gas supplying portion 7 is connected to a supply source 75 for a C₅F₈ gas as a raw material gas through the second gas supplying path 73, and the C₅F₈ gas flows through the second gas supplying path 73 and then through the gas flow path 72 and is uniformly supplied to the space below the second gas supplying portion 7 through the second gas supplying holes 71, as illustrated in FIG. 2. In the present embodiment, a means for supplying the processing chamber 5 with the C₅F₈ gas is constituted by the supply source 75, the second gas supplying path 73, and the second gas supplying portion 7. In FIG. 2, reference characters V1 and V2 denote valves, and reference numeral 101 denotes a flow rate adjusting means for adjusting a quantity of an Ar gas supplied into the processing chamber 5, and reference numeral 102 denotes a flow rate adjusting means for adjusting a quantity of the C₅F₈ gas supplied into the processing chamber 5.

As illustrated in FIG. 2, a cover plate 53 composed of a dielectric substance such as aluminum oxide is disposed on an upper surface of the first gas supplying portion 6 so as to be sealed together by using a seal member (not shown) such as an O-ring, and an antenna member 8 is disposed on an upper surface of the cover plate 53 so as to be closely attached to the cover plate 53. As illustrated in FIG. 4, the antenna member 8 includes a flat antenna main body 81 in which a lower surface having a circular shape in a plane is open, and a planar antenna member (slot plate) 82 disposed to close the open lower surface of the antenna main body 81 and having the shape of a circular plate in which a plurality of slots are formed. The antenna main body 81 and the planar antenna member 82 are composed of a conductor and constitute a flat, hollow circular waveguide. In addition, the cover plate 53 is connected to the lower surface of the planar antenna member 82.

In addition, a wavelength-shortening plate 83 is disposed between the planar antenna member 82 and the antenna main body 81 and is composed of a low-loss dielectric substance such as aluminum oxide or silicon nitride (Si₃N₄). The wavelength-shortening plate 83 is used to shorten the wavelength of microwaves in order to shorten the wavelength inside a circular waveguide. In the present embodiment, a radial line slot antenna, that is, the antenna member 8, is constituted by the antenna main body 81, the planar antenna member 82, and the wavelength-shortening plate 83.

The antenna member 8 having the above structure is installed on the processing chamber 5 by using a seal member (not shown) so that the planar antenna member 82 is closely attached to the cover plate 53. The antenna member 8 is connected to a microwave generating means 85, which is outside the processing chamber 5, through a coaxial waveguide 84 so that microwaves having a frequency of 2.45 GHz or 8.3 GHz are supplied to the antenna member 8. In this case, a waveguide 84A corresponding to an outer portion of the coaxial waveguide 84 is connected to the antenna main body 81, and a central conductor 84B is connected to the planar antenna member 82 through the opening formed in the wavelength-shortening plate 83.

The planar antenna member 82 is formed of a copper plate having a thickness of about 1 mm, for example, and as illustrated in FIG. 4, a plurality of slots 86 are formed in the planar antenna member 82 so as to generate circularly polarized waves, for example. The slots 86 are each formed by a pair of slots 86a and 86b disposed very slightly apart from each other to form an approximately T shape, and are arranged along a circumferential of the copper plate so as to form a concentric circular shape or vortex shape, for example. Since each pair of slots 86a and 86b are arranged to be approximately perpendicular to each other as described above, a circularly polarized wave including two perpendicular polarized wave components is irradiated. In this case, a distance between adjacent slots 86 is set as a distance corresponding to the wavelength of microwaves compressed by the wavelength-shortening plate 83 so that the microwaves are irradiated in the form of approximately planar waves from the planar antenna member 82. In the present invention, a plasma generating means is constituted by the microwave generating means 85, the coaxial waveguide 84, and the antenna member 8.

In addition, as illustrated in FIG. 2, an exhaust pipe 54 is connected to the bottom part of the processing chamber 5. The exhaust pipe 54 is connected to a vacuum pump 56 as an evacuating means through a pressure adjusting portion 55, which constitutes a pressure adjusting means, so that the processing chamber 5 can be vacuumized to a predetermined pressure.

Here, supplying of a power to the microwave generating means 85 or the high frequency power supply source 52, opening and closing of the valves V1 and V2 for supplying a plasma gas or a raw material gas, the flow rate adjusting means 101 and 102, and the pressure adjusting portion 55 are controlled by a control means 200 being a computer, based on a program into which film forming steps are entered to form a CF film under a predetermined conditions. The program is stored in a storage medium 201 such as a flexible disk, a compact disk, a flash memory or a magneto-optical (MO) disk and thus is installed in the control means 200.

Subsequently, an embodiment of a film forming method according to the present invention that is performed by using the above-described film forming apparatus will be described. First, the wafer W as a substrate having copper wiring, for example, formed on the surface thereof is carried into the processing chamber 5 through a gate valve (not shown) and is placed on the loading table 51. Subsequently, the inside of the processing chamber 5 is vacuumized to a predetermined pressure, and a plasma gas excited by microwaves, for example, an Ar gas, is supplied to the first gas supplying portion 6 through the first gas supplying path 63 at a predetermined flow rate of 300 sccm, for example. Meanwhile, a C₅F₈ gas as a raw material gas is supplied to the second gas supplying portion 7 as a raw material gas supplying portion through the second gas supplying path 73 at a predetermined flow rate of 200 sccm, for example. The inside of the processing chamber 5 is maintained at a process pressure of 7.32 Pa (55 m Torr), for example, and the surface temperature of the loading table 51 is set to 420° C.

Meanwhile, when a high frequency (microwaves) power of 2.45 GHz and 2750 W is supplied from the microwave generating means 85, the microwaves are propagated through the coaxial waveguide 84 in a TM mode, a TE mode or a TEM mode and reach the planar antenna member 82 of the antenna member 8. While the microwaves pass through the central conductor 84B of the coaxial waveguide 84 and are propagated from a central portion of the planar antenna member 82 toward a peripheral area thereof in a radial shape, the microwaves are emitted from each pair of slots 86a and 86b toward a processing space below the first gas supplying portion 6 through the cover plate 53 and the first gas supplying portion 6.

Here, the cover plate 53 and the first gas supplying portion 6 are formed of a material through which microwaves can be transmitted, for example, composed of aluminum oxide, and thus act as a microwave transmitting window. Thus, the microwaves are efficiently transmitted by the cover plate 53 and the first gas supplying portion 6. In this case, since the pairs of slots 86a and 86b are arranged as described above, circularly polarized waves are uniformly emitted onto the entire flat surface of the planar antenna member 82 so that the electric field density of the processing space below the first gas supplying portion 6 becomes uniform. High-density uniform plasma is excited on the entire area of the processing space, which is wide, due to an energy of the microwaves. That is, a gas for generating plasma is plasmatized. The plasma (plasmatized gas for generating plasma) flows into a processing space below the second gas supplying portion 7 through the opening 74 of the second gas supplying portion 7 and activates the C₅F₈ gas supplied to the processing space from the second gas supplying portion 7, i.e., plasmatizes the C₅F₈ gas, thereby forming an active species.

After that, the active species is transported to the surface of the wafer W, and a power of about 100 W, for example, is applied to the loading table 51 from the biasing high frequency power supply source 52, and the active species is deposited due to an energy generated by the power, and the CF film is formed. The wafer W in which the CF film is formed, is carried out of the processing chamber 5 through the gate valve (not shown). A series of operations wherein the wafer W is carried into the processing chamber 5 and is processed under a predetermined conditions, and the wafer W is carried out of the processing chamber 5 are performed by reading the program by using the control means 200 as described previously.

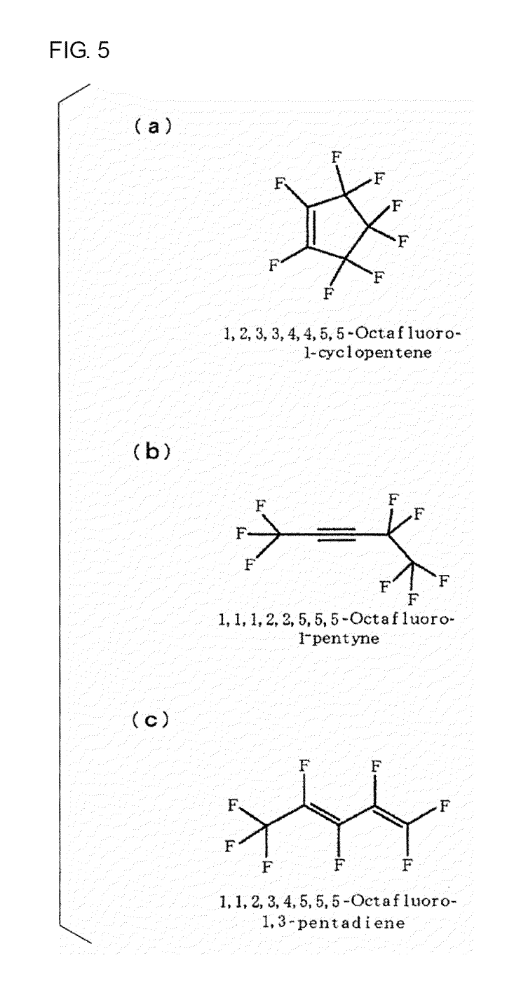

For example, as illustrated in FIG. 5, the C₅F₈ gas may include a C₅F₈ gas having a ring-shaped structure (1,2,3,3,4,4,5,5-Octafluoro-1-cyclopentene, see (a) of FIG. 5), a C₅F₈ gas having a straight chain-shaped structure which contains a triple bond (1,1,1,2,2,5,5,5-Octafluoro-1-pentyne, see (b) of FIG. 5), and a C₅F₈ gas having a straight chain-shaped structure which contains a coupled double bond (1,1,2,3,4,5,5,5-Octafluoro-1,3-pentadiene, see (c) of FIG. 5).

In the above-described embodiment, the C₅F₈ gas may be activated by plasma having a low electron temperature of 3 eV or less near the surface of the wafer W. This is because the gas for generating plasma such as an Ar gas is supplied from a space above the processing chamber 5 and is plasmatized and the C₅F₈ gas is plasmatized by the gas for generating plasma plasmatized. Thus, the C₅F₈ gas is not excessively dissociated, and excessive decomposition may be suppressed, and an original molecular structure having the characteristic of the C₅F₈ gas may be obtained. Since deposition of the active species is performed and a low biasing high frequency power is applied on the wafer W, the elastic modulus and hardness of the CF film are improved, as known from an experimental example that will be described later, and a good leak characteristic of the CF film is obtained, and a linear expansion coefficient of the CF film is small.

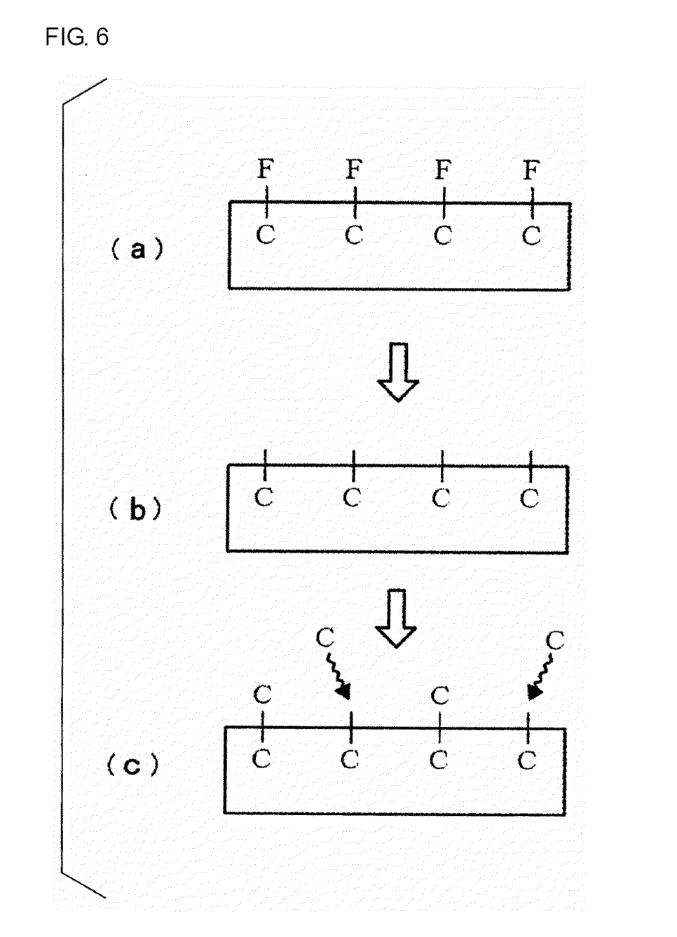

The reason why the characteristic of the CF film is improved is supposed as below. As illustrated in FIG. 6, first, the active species in the plasma is brought into the surface of the wafer W, and a C—F bond is tentatively formed on the surface of the deposited active species ((a) of FIG. 6). Next, due to an energy generated by the weak biasing power, the C—F bond is cut off, and a dangling bond is formed ((b) of FIG. 6). Next, C is coupled to the dangling bond, and a C—C bond is formed ((c) of FIG. 6). As such, it is supposed that the rate of the C—C bond inside the CF film increases.

Thus, the mechanical strength such as the elastic modulus and hardness of the CF film may be improved, peeling of the film is suppressed when a stress is applied during a process of fabricating a semiconductor device and the breaking of the interlayer insulating film is suppressed even when a large force is applied during a CMP process. In addition, the occurrence of a problem such as peeling of the film or wiring disconnection may be reduced even when thermal stress is applied during the process of fabricating the semiconductor device, from the viewpoint of a small linear expansion coefficient of the CF film. Even when the number of C—C bond increases, an increase in relative permittivity of the CF film is suppressed, and thus, an advantage of a low permittivity film is not lost.

Here, regarding the magnitude of the biasing high frequency power during film forming, as the biasing power increases, the elastic modulus and hardness of the CF film increase to 100 W from an example that will be described later, and any improvement cannot be found at 100 W or more. Thus, a value of the biasing power is within a range in which the elastic modulus and hardness of the CF film remarkably increase compared to the case where the biasing power is not applied, and when the value of the biasing power is so large, the CF film is damaged, and thus, the biasing power needs to be less than 100 W. In the following experiment, a wafer having the size of 8-inch is used, and the size of the wafer W is nearly the same as that of a top surface of the loading table 51, and thus, the biasing high frequency power needs to be applied to the loading table 51 so that the biasing high frequency power of 0.32 W/cm² or less is applied on the wafer W per unit area.

(Another Example of Application)

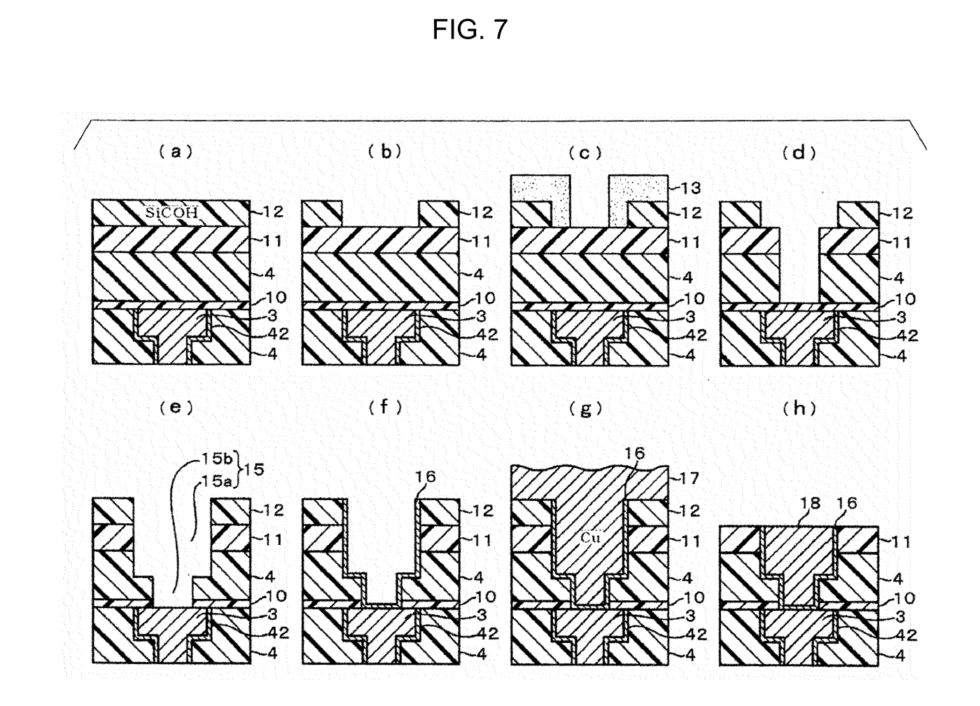

Next, an example in which the CF film obtained by the above-described film forming method is used will be described. In the present example, the CF film according to the present invention is used as an interlayer insulating film, and several films for forming an electrode for wiring are laminated on the interlayer insulating film. The embodiment of the case where a (n+1)-th wiring circuit portion is formed on an n-th (where n is an integer of 1 or more) wiring circuit portion will be described with reference to FIG. 7, for example. In addition, in FIG. 7, the same type of film as the wiring circuit portion of FIG. 1 refers to the same reference numeral.

First, a SiCN film 10 used as a barrier film, each of the interlayer insulating films 4 being the CF film according to the present invention, a SiCN film 11 used as a hard mask, and a SiCOH film 12 are sequentially laminated on the n-th wiring circuit portion ((a) of FIG. 7). In addition, the SiCOH film 12 also acts as a hard mask. Subsequently, a resist mask (not shown) is formed on the SiCOH film 12. Next, the SiCOH film 12 is etched by plasma including an active species of a halide by using the resist mask so that the SiCOH film 12 having a predetermined pattern is formed ((b) of FIG. 7).

After that, a resist film 13 is formed on the surface of the SiCOH film 12 and the SiCN film 11. In this case, a narrower pattern than the predetermined pattern is formed ((c) of FIG. 7). Next, the SiCN film 11 is etched by plasma including the active species of the halide, for example, by using the resist mask 13, and subsequently, the CF film 4 according to the present invention is etched by oxygen plasma, for example, and the resist film 13 is removed ((d) of FIG. 7).

After that, when, by using the SiCOH film 12 as a mask, the SiCN film 10 as a barrier film and the SiCN film 11 as a hard mask are etched by plasma including the active species of the halide, for example and by using the mask 12, the CF film 4 is etched by oxygen plasma, a recess portion having a larger width compared to a recess portion formed by previous etching is formed ((e) of FIG. 7). In addition, a recess portion 15b having a small width corresponds to a via hole, and a recess portion 15a having a large width corresponds to a wiring burying area (trench) of a circuit of the wiring circuit portion.

After that, a conductive barrier film 16 as a laminated film of tantalum (Ta) and titanium (Ti), for example, is formed on the surface of the recess portion 15 ((f) of FIG. 7), and a copper (Cu) metal 17 is buried on the recess portion 15 ((g) of FIG. 7). After that, all or a part of the surplus Cu metal 17, the SiCOH film 12, and the SiCN film 11 is removed by CMP, and a wiring 18 that is electrically connected to the copper wiring 3 is formed, and the (n+1)-th wiring circuit portion is formed ((h) of FIG. 7).

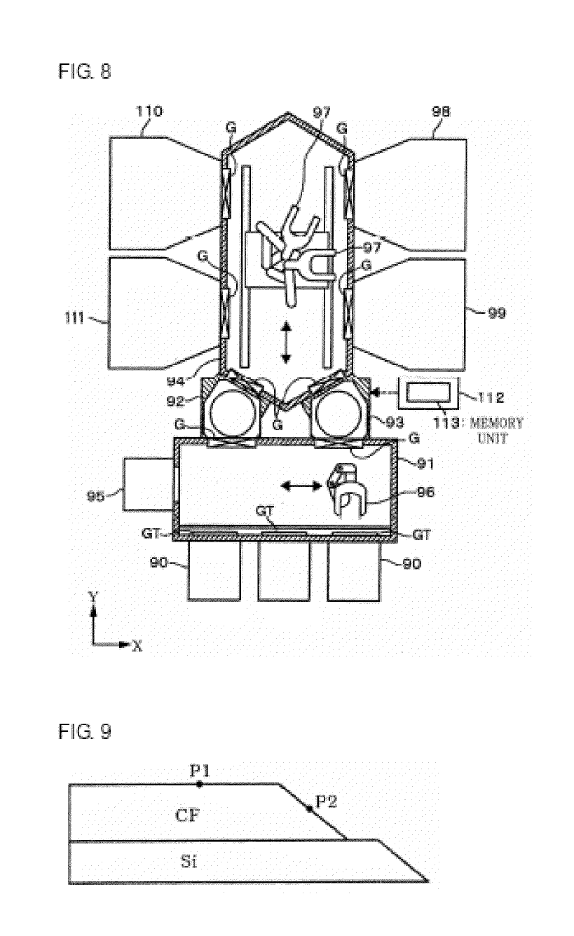

Next, an example of an apparatus for fabricating a semiconductor for performing a method of fabricating a laminate of (a) of FIG. 7 will be described with reference to FIG. 8. In FIG. 8, 90 denotes a carrier, 91 denotes a first transfer chamber, 92 and 93 denote load lock chamber for adjusting atmosphere when the wafer W is transferred, 94 denotes a second transfer chamber, and 95 denotes an alignment chamber. The first transfer chamber 91 is maintained at an atmosphere, and the second transfer chamber 94 is maintained at a vacuum atmosphere. In FIG. 8, 96 denotes a first transfer means, and 97 denotes a second transfer means. In addition, a film forming apparatus 98 shown in FIGS. 2 through 4, for forming each of the interlayer insulating films 4 being a CF film according to the present invention, a plasma film forming apparatus 99 for forming the SiCN films 10 and 11, a film forming apparatus 110 for forming the SiCOH film 12, and an annealing apparatus 111 for annealing the wafer W at a N₂ gas atmosphere, for example, at a temperature of about 400° C. for example, are air tightly connected to the second transfer chamber 94. In addition, G of FIG. 8 is a gate valve (partition valve) that partitions between the load lock chambers 92 and 93 and the first transfer chamber 91 or the second transfer chamber 94 or between the second transfer chamber 94 and the film forming apparatuses 98, 99, and 110 or the annealing apparatus 111. In addition, GT of FIG. 8 is a door.

In addition, a controller 112 constituted by a computer, for example, is disposed on the apparatus 9 for fabricating the semiconductor, as illustrated in FIG. 8, and the controller 112 includes a data processing unit including a program, a memory, and a central processing unit (CPU). Among them, commands (each step) in which a control signal is transmitted to each unit of the apparatus 9 for fabricating the semiconductor from the controller 112 and a transfer order that will be described later proceeds, are stored in the program. In addition, values of processing parameters such as a processing pressure, a processing temperature, a processing time, a gas flow rate or a power value of each of the apparatuses 98, 99, 110, and 111 are written in the memory, for example, so that, when the CPU executes each of the commands of the program, the processing parameters are read out and a control signal according to each of the parameter values is transmitted to each portion of the apparatus 9 for fabricating the semiconductor. The program (including a program related to input manipulation or display of processing parameters) is stored in a memory unit 113 as a computer storage medium such as a flexible disk, a compact disk, a hard disk or a magneto-optical (MO) disk and thus is installed in the controller 112.

Next, a transferring route of the apparatus 9 for fabricating the semiconductor according to the present embodiment will be described. First, the wafer W inside the carrier 90 is transferred to the first transfer means 96->the load lock chamber 92 or 93->the second transfer means 97->the film forming apparatus 99, and the SiCN film 10 used as the barrier film is formed by the film forming apparatus 99. After that, the wafer W is transferred to the film forming apparatus 98 through the second transfer means 97, and each of the interlayer insulating films 4 being the CF film according to the present invention is formed on the SiCN film 10. After that, the wafer W is transferred to the film forming apparatus 99 through the second transfer means 97, and the SiCN film 11 used as a hard mask is formed on each of the interlayer insulating films 4. After that, the wafer W is transferred to the film forming apparatus 110 through the second transfer means 97, and the SiCOH film 12 is formed on the SiCN film 11. After that, the wafer W is returned in a pathway of the second transfer means 97->the load lock chamber 92 or 93->the first transfer means 96->the carrier 90.

Here, as the film forming apparatus 99 for forming the SiCN films 10 and 11 and the apparatus 110 for forming the SiCOH film 12, a CVD apparatus shown in FIGS. 2 through 4 described previously may be used. In other words, in the film forming apparatus 99, in the CVD apparatus shown in FIGS. 2 through 4 described previously, the supply source of a plasma gas, for example, an Ar gas and the supply source of a nitrogen gas are connected to the first gas supplying path 63, and a supply source of a trimethylsilane gas is connected to the second gas supplying path 73. In addition, in the film forming apparatus 110, in the CVD apparatus shown in FIGS. 2 through 4 described previously, the supply source of a plasma gas, for example, an Ar gas and the supply source of an oxygen gas are connected to the first gas supplying path 63, and a supply source of a trimethylsilane gas is connected to the second gas supplying path 73. In addition, the annealing apparatus 111 includes a processing chamber in which a loading table, a heater for heating the wafer W, and a means for supplying a N₂ gas are provided.

In addition, in the laminate body containing the CF film according to the present invention shown in FIG. 7, a SiCN film is used as a barrier film formed under the CF film 4 and a hard mask formed on the CF film 4. However, a SiC film, a SiN film, an amorphous carbon film or an Si-added amorphous carbon film may be used, instead of the SiCN film. By using the films, the apparatus 9 for fabricating the semiconductor described previously may be used as an apparatus for laminating a film, as illustrated in (a) of FIG. 7. In addition, as a film forming apparatus for forming an amorphous carbon film, in the apparatus shown in FIGS. 2 through 4 described previously, the supply source of a plasma gas, for example, an Ar gas is connected to the first supplying path 63, and a supply source of a 2-butyne (C₄H₆) gas is connected to the second supplying path 73. In addition, as a film forming apparatus for forming an amorphous carbon film, in the apparatus shown in FIGS. 2 through 4 described previously, the supply source of a plasma gas, for example, an Ar gas is connected to the first supplying path 63, and a supply source of a 2-butyne (C₄H₆) gas and a Si₂H₆ (disilane) gas is connected to the second supplying path 73. Here, as a composition of the amorphous carbon film, a ratio (H/C) of a carbon atom C to a hydrogen atom H of the amorphous carbon film is between 0.8 and 1.2, and more preferably, between 0.9 and 1.1. In addition, as a composition of the Si-added amorphous carbon film, silicon (Si) of 10 atomic percent or less is included, and more preferably, 5 atomic percent or less Si is included. After the amorphous carbon films are formed, annealing process is performed by the annealing apparatus 111, and a dangling bond that is incorporated during film forming is removed.

In addition, the CF film according to the present invention is formed on at least an inner wall surface of an electrolytic cell for purifying a high-concentration of alkaline solution and may be used as a corrosion resistant film. In addition, in a stack of a borohydride fuel cell, the CF film according to the present invention is formed on an inner wall surface of a separator for holding a fuel electrode, an electrolyte permeating film, and an oxidizing agent electrode and may be used as a corrosion resistant film.

### EXAMPLES

### A. Regarding Composition of Fluorine-Added Carbon Film

### Experimental Example 1

By using the already-described plasma film forming apparatus, a CF film was formed on a bare silicon wafer under the following conditions, so that a thickness of the CF film was about 150 nm. Next, the CF film was cut off to be tilted to one side, as illustrated in FIG. 9, and the state of a chemical bond of carbon C1s on a surface P1 of the CF film and on a cross-section P2 of the CF film was measured by X-ray photoelectron spectroscopy (XPS) analysis.

(Film Forming Conditions)

Power of microwaves: 2750 W

Processing pressure: 55 m Torr (7.33 Pa)

Processing gas: stated in a separate paragraph

Power of a lower electrode: stated in a separate paragraph

### Example 1-1

Processing gas: C₅F₈/Ar=150/300 sccm

Power of a lower electrode: 300 W

### Example 1-2

Processing gas: C₅F₈/Ar=200/300 sccm

Power of a lower electrode: 50 W

### Comparative Example 1

Processing gas: C₅F₈/Ar=200/300 sccm

Power of a lower electrode: film was formed without supplying a power

(Experimental Result)

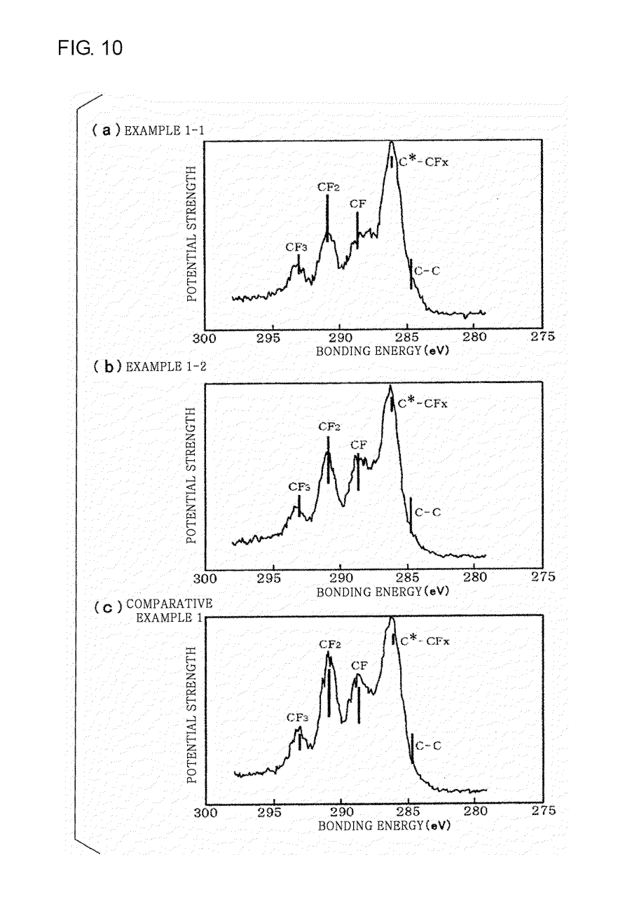

Results of the above-described examples 1-1 and 1-2 and the comparative example 1 are shown in (a), (b), and (c) of FIG. 10. In addition, from the results, a ratio of the surface P1 to the cross-section P2 of the CF film was calculated according to types of carbon bonds. In addition, apart from the results, a ratio F/C as a ratio of fluorine to carbon was calculated by using XPS and was summarized in the following Table 1. In addition, even though ratios of the surface P1 to the cross-section P2 of the CF film according to types of carbon bonds were summed, 100% was not obtained because a (C═O) bond other than these bond species existed. It was supposed that the bond species were formed by oxygen that was brought into the processing chamber in a small amount.

TABLE 1

| | CF₃ | CF₂ | CF | C—C | C*—CFₓ | F/C Ratio |
|---|---|---|---|---|---|---|
| Example 1-1 | 7.4% | 17.5% | 17.4% | 7.2% | 40.2% | 0.73~0.74 |
| Example 1-2 | 8.0% | 19.7% | 20.6% | 5.1% | 37.1% | 0.85 |
| Comparative | 8.7% | 22.6% | 21.2% | 2.2% | 38.0% | 0.95~0.97 |
| Example1 | | | | | | |

As a result, in the examples 1-1 and 1-2, a bond between carbon and fluorine was reduced and a bond between carbon and carbon increased compared to the comparative example 1. In addition, from the result of calculating the F/C ratio, in the examples 1-1 and 1-2, fluorine was detached from the CF film. Thus, from the viewpoint, it was considered that fluorine that was coupled to carbon inside the CF film was detached from the CF film, so that carbon was coupled to carbon that had been coupled to fluorine and a bond between carbon and carbon was formed. In addition, there was no difference between both the surface P1 of the CF film and the cross-section P2 of the CF film. In other words, the inside of the CF film had the same composition as that of the surface of the CF film.

From the viewpoint, as already described, it was supposed that a biasing power was supplied to the CF film, so that fluorine inside the CF film was formed due to ions.

### B. Regarding Leak Characteristic

### Experimental Example 2

A CF film was formed under the following conditions that were the same as that of The above-described experimental example 1 except for the following film forming conditions. After that, an electric field of 1 MV/cm was applied to the CF film and a leak current density was measured by using a mercury probe.

(Film Forming Conditions)
Processing gas: C₅F₈/Ar=150, 200/300 sccm
Power of a lower electrode: was set as below according to a flow rate of the C₅F₈ gas
150 sccm: 20, 30, 50, 70, 100, 300 W
200 sccm: 0, 20, 50, 100, 300 W

In addition, the power of the lower electrode was set as above, because an experimental conditions were changed on each case while an experiment was performed, and an experiment that was considered to be supposed by other data was omitted. This applies to the following experiment.

(Experimental Result)

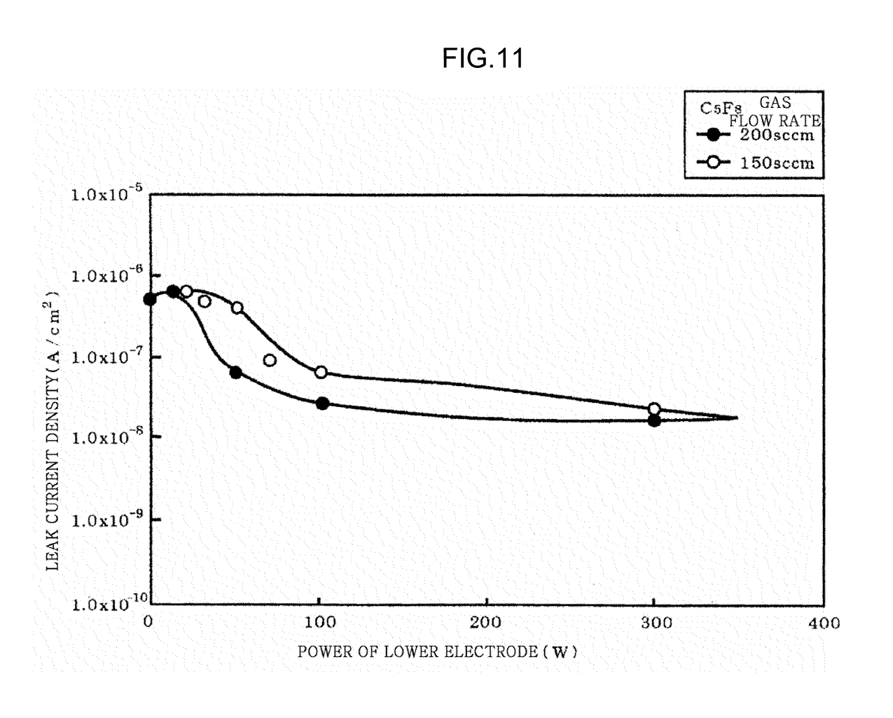

The result was shown in FIG. 11. From the result, as the power supplied to the lower electrode increased, the leak current density was reduced. In particular, leak current density was rapidly reduced by two digits until when the power of about 100 W was applied. In addition, in particular, when the flow rate of the C₅F₈ gas was 200 sccm, a good result was obtained.

Even from the result of the experimental example 1, it was considered because the biasing power was supplied from the lower electrode so that fluorine was detached from the CF film, a bond between carbon and carbon increased and electrons that are capable of freely moving inside the CF film were reduced (the number of dangling bonds was reduced).

### C. Regarding Mechanical Strength

### Experimental Example 3

A CF film was formed under the following conditions that were the same as that of the above-described experimental example 1 except for the following film forming conditions. When a mechanical strength of the CF film was measured, the CF film was formed to have a thickness of 1 μm so as not to be affected by the strength of a bare silicon wafer as a substrate. After that, a hardness and a Young's modulus of the CF film were measured by using a nano indenter.

(Film Forming Conditions)
Processing gas: C₅F₈/Ar=150, 200/300 sccm
Power of a lower electrode: was set as below according to a flow rate of the C₅F₈ gas
150 sccm: 50, 70, 100, 300 W
200 sccm: 20, 30, 100 W

(Experimental Result)

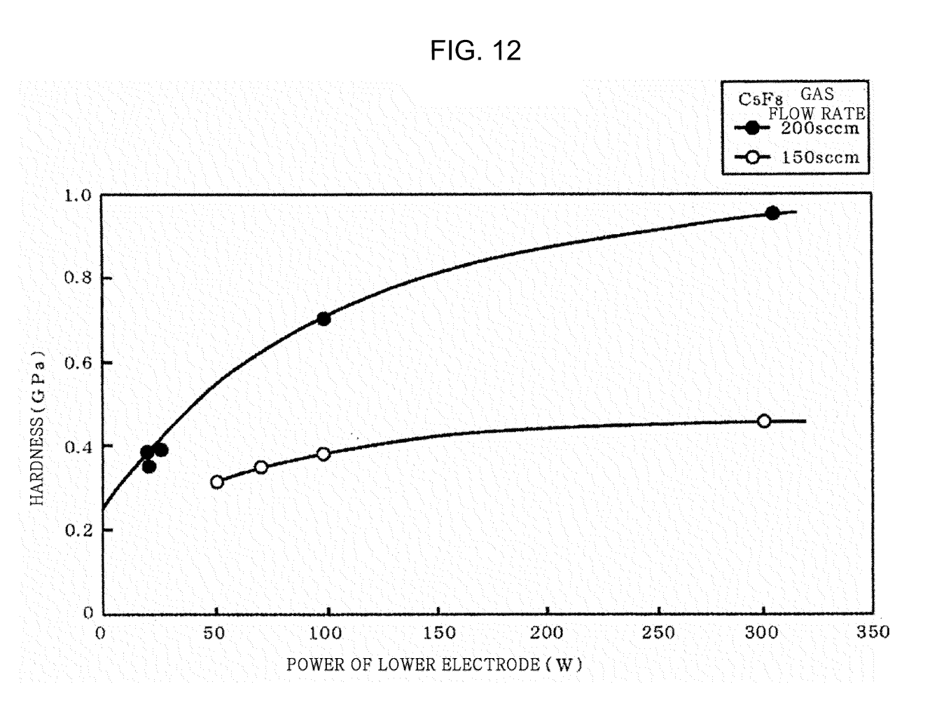

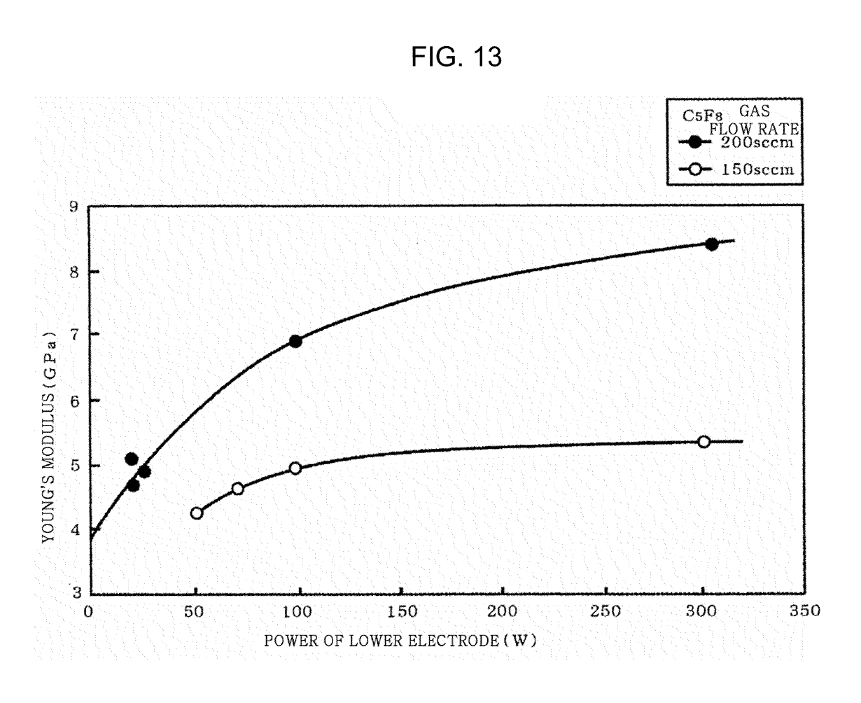

Results of the hardness and the Young's modulus were shown in FIGS. 12 and 13. As powers applied to all lower electrodes increased, both of the hardness and the Young's modulus increased and as the flow rate of C₅F₈ increased, both of the hardness and the Young's modulus increased remarkably.

It was considered that mechanical strength of a bond between carbon and carbon that was increased by a biasing power was larger than that of a bond between carbon and fluorine. In addition, it was considered that the quantity of carbon increased (the flow rate of the C₅F₈ gas increased), and for example, a bond between carbon and carbon was complicatedly formed in the net-like.

### D. Regarding Film Forming Speed

### Experimental Example 4

A CF film was formed under the following conditions that were the same as that of the above-described experimental example 1 except for the following film forming conditions. After that, the thickness of the CF film was measured to calculate the film forming speed of the CF film.

(Film Forming Conditions)
Processing gas: C₅F₈/Ar=150, 200/300 sccm
Power of a lower electrode: was set as below according to a flow rate of the C₅F₈ gas
150 sccm: 50, 70, 100, 300 W
200 sccm: 0, 50, 100, 300 W

(Experimental Result)

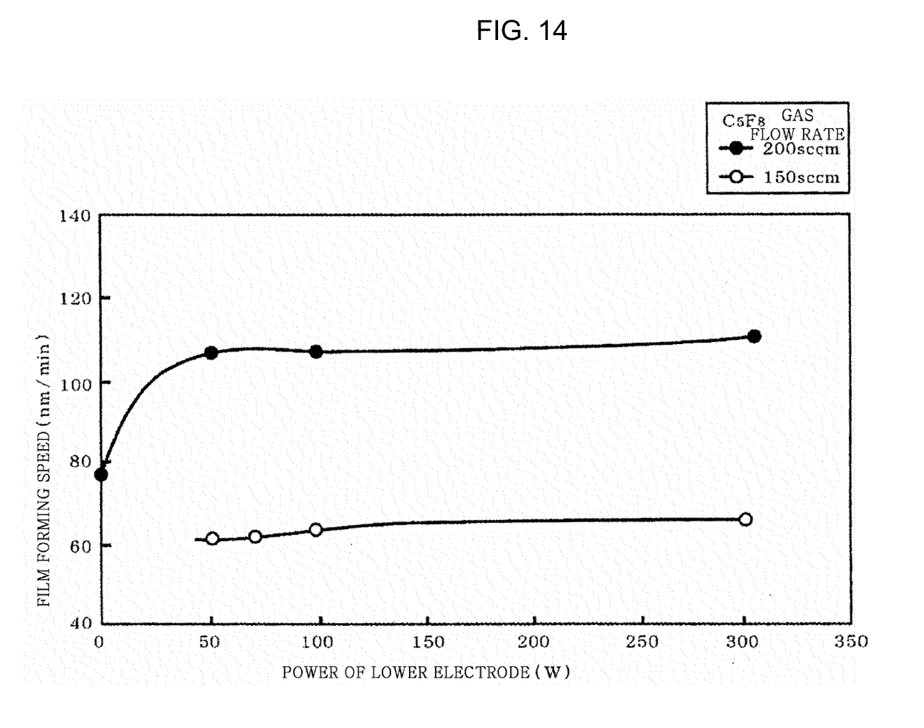

The result was shown in FIG. 14. It was considered that the film forming speed increased rapidly when the power of the lower electrode was to about 50 W and after that, increased gently. From the viewpoint, it was considered that the biasing power was applied so that a force for dragging ions that were generated by decomposing the C₅F₈ gas was strong and the film forming speed increased to some degree (about 50 W) but after that, the quantity of dragging ions and the quantity of etching the formed CF film were competed with each other. In addition, as the flow rate of the C₅F₈ gas increased, the film forming speed was improved.

### E. Regarding Relative Permittivity

### Experimental Example 5

A CF film was formed under the following conditions that were the same as that of the above-described experimental example 1 except for the following film forming conditions. After that, relative permittivity was measured by using a mercury probe.

(Film Forming Conditions)
Processing gas: C₅F₈/Ar=150, 200/300 sccm
Power of a lower electrode: was set as below according to a flow rate of the C₅F₈ gas
150 sccm: 20, 30, 50, 70, 100, 300 W
200 sccm: 0, 50, 100, 300 W

(Experimental Result)

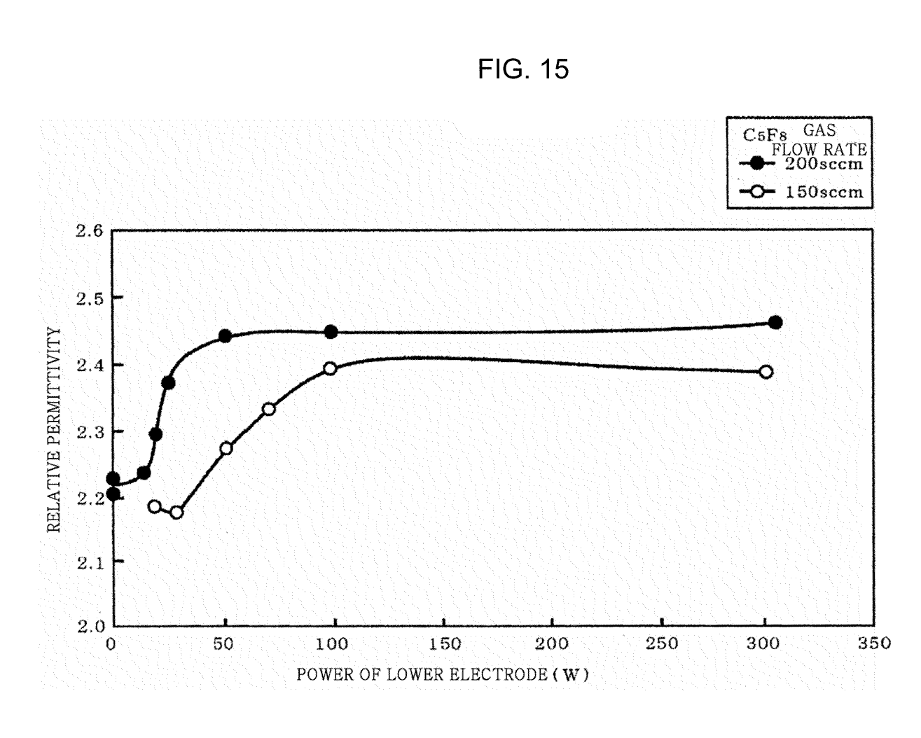

The result was shown in FIG. 15. Even in the experiment, as clarified in the above-described experimental examples 1 and 2, detachment of fluorine from the CF film was identified. In other words, an increase in relative permittivity that was considered to be accompanied with detachment of fluorine was identified. Like in the above experiment, as the power of the lower electrode and the flow rate of C₅F₈ gas increased, relative permittivity increased remarkably but the quantity of relative permittivity was very small and even though the quantity of relative permittivity was at maximum, the quantity of an increase in relative permittivity was between 0.2 and 0.3. Thus, a low relative permittivity characteristic that is an advantage of the CF film was obtained.

### F. Regarding Coefficient of Thermal Expansion (CTE)

### Experimental Example 6

A CF film was formed under the following conditions that were the same as that of the above-described experimental example 1 except for the following film forming conditions. After that, a coefficient of thermal expansion (CTE) of the CF film was measured by using an X-ray mirror surface reflection measurement method. In other words, the thickness of the CF film was measured by using an X-ray when a temperature increase and a temperature decrease were performed at a temperature between 30° C. and 400° C. to calculate the CTE. In addition, in order to check reproducibility of the experiment, measurements were each performed three times.

(Film Forming Conditions)

### Example 6-1

Processing gas: C₅F₈/Ar=150/300 sccm

Power of a lower electrode: 300 W

### Example 6-2

Processing gas: C₅F₈/Ar=200/300 sccm

Power of a lower electrode: 50 W

(Experimental Result)

The CTE of a CF film that was obtained as the result of experiment was shown in the following Table 2 according to a temperature increase and a temperature decrease.

TABLE 2
Unit: ppm/° C.

| | | Example 6-1 | Example 6-2 |
|---|---|---|---|
| First time | During temperature | 35 | 48 |
| | Increase | | |
| | During temperature | 40 | 62 |
| | Decrease | | |
| Second | During temperature | 38 | 55 |
| time | Increase | | |
| | During temperature | 40 | 61 |
| | Decrease | | |
| Third time | During temperature | 40 | 59 |
| | Increase | | |
| | During temperature | 42 | 64 |
| | Decrease | | |

From the result and the viewpoint that the CTE of the CF film was about 90 ppm/° C. when a biasing power was not applied to the lower electrode, in both Examples 6-1 and 6-2, the CF film when the biasing power was applied to the lower electrode had a small CTE and small volume variation due to heating or cooling and thus, peeling of the film due to temperature variation does not easily occur. In addition, during heating (temperature increase) and during cooling (temperature decrease), from the viewpoint of a small difference in CTE, firing deformation does not easily occur due to heat (i.e., returned to an original size even when heating or cooling was repeatedly performed) and thus, it was considered that peeling of the film does not easily occur at an interface between the CF film and a bare silicon wafer as a substrate.

### G. Regarding Annealing after Film Forming

### Experimental Example 7

A CF film was formed under the following conditions that were the same as that of the above-described experimental example 1 except for the following film forming conditions. After that, a Ti film, a Ta film, and a Cu film were laminated on the CF film by CVD in this sequence, and annealing was performed at a wafer temperature of 400° C. for 20 minutes to observe the surface of the Cu film.

(Film Forming Conditions)
Processing gas: C₅F₈/Ar=150/300, 200/300 sccm
Power of a lower electrode: was set as below according to a flow rate of the C₅F₈ gas
150 sccm: 100, 300 W
200 sccm: 30, 50 W

(Experimental Result)

A spotted discoloration area was shown only in a wafer in which the biasing power of 300 W was applied to the lower electrode. From the viewpoint, it was supposed that, when so large biasing power was applied to the lower electrode that the CF film was damaged and degassing from the CF film happened during annealing.

While this invention has been particularly shown and described with reference to exemplary embodiments thereof, it will be understood by those skilled in the art that various changes in form and details may be made therein without departing from the spirit and scope of the invention as defined by the appended claims.

1. A film forming method comprising:
placing a substrate on a loading portion inside a processing chamber;
supplying a gas for generating plasma, which is excited by microwaves, into the processing chamber;
evacuating an inside of the processing chamber;
supplying a C₅F₈ gas into the processing chamber;
supplying microwaves into the processing chamber from a planar antenna member, which is disposed on an upper part of the processing chamber to face the loading portion and in which a plurality of slots are formed along a circumferential direction, and plasmatizing the gas inside the processing chamber;
forming a fluorine-added carbon film on the substrate by the plasmatized gas; and
applying a biasing high frequency power to the loading portion while forming the fluorine-added carbon film on the substrate so that the biasing high frequency power of 0.32 W/cm² or less is applied on the substrate per unit area.

2. The method of claim 1, wherein the C₅F₈ gas comprises an octafluorocyclopentene gas, an octafluoropentyne gas or an octafluoropentadiene gas.

3. The method of claim 1, wherein the fluorine-added carbon film is an insulating film included in a semiconductor device.

4. A film forming apparatus comprising:
a processing chamber having an air tight structure;
a loading portion, which is formed inside the processing chamber and on which a substrate is placed;
a waveguide situated lateral to the processing chamber and guiding microwaves to one end of the waveguide;
a planar antenna member, which is disposed on the processing chamber and is connected to one end of the waveguide to face the loading portion and in which a plurality of slots for supplying microwaves introduced by the waveguide into the processing chamber are formed along a circumferential direction;
a plasma gas supplying means disposed on the processing chamber and supplying a gas for generating plasma excited by the microwaves into the processing chamber;
a C₅F₈ gas supplying means disposed on the processing chamber separately from the plasma gas supplying means and supplying a C₅F₈ gas into the processing chamber;
an exhaust means for evacuating an inside of the processing chamber; and
a high frequency power applying means for applying a biasing high frequency power to the loading portion so that the biasing high frequency power of 0.32 W/cm² or less is applied on the substrate per unit area,
wherein the gas supplied into the processing chamber is plasmatized by microwaves from the planar antenna member, and a fluorine-added carbon film is formed on the substrate by the plasmatized gas.

5. The apparatus of claim 4, further comprising a control means for controlling the plasma gas supplying means, the C₅F₈ gas supplying means, the planar antenna member, and the high frequency power applying means by receiving outputs of control commands.

6. The apparatus of claim 4, wherein one slot and the other slot formed in the planar antenna member are disposed to form an approximately T shape.

7. A storage medium in which a computer program for executing a film forming method on a computer is stored, wherein the film forming method comprises:
placing a substrate on a loading portion inside a processing chamber;
supplying a gas for generating plasma, which is excited by microwaves, into the processing chamber;
evacuating an inside of the processing chamber;
supplying a C₅F₈ gas into the processing chamber;
supplying microwaves into the processing chamber from a planar antenna member, which is disposed on an upper part of the processing chamber to face the loading portion and in which a plurality of slots are formed along a circumferential direction, and plasmatizing the gas inside the processing chamber;
forming a fluorine-added carbon film on the substrate by the plasmatized gas; and
applying a biasing high frequency power to the loading portion while forming the fluorine-added carbon film on the substrate so that the biasing high frequency power of 0.32 W/cm² or less is applied on the substrate per unit area.

8. A semiconductor device comprising an insulating film, wherein the insulating film is comprised of a fluorine-added carbon film, which is formed by a film forming method, wherein the film forming method comprises:
placing a substrate on a loading portion inside a processing chamber;
supplying a gas for generating plasma, which is excited by microwaves, into the processing chamber;
evacuating an inside of the processing chamber;
supplying a C₅F₈ gas into the processing gas;
supplying microwaves into the processing chamber from a planar antenna member, which is disposed on an upper part of the processing chamber to face the loading portion and in which a plurality of slots are formed along a circumferential direction, and plasmatizing the gas inside the processing chamber;
forming a fluorine-added carbon film on the substrate by the plasmatized gas; and
applying a biasing high frequency power to the loading portion while forming the fluorine-added carbon film on the substrate so that the biasing high frequency power of 0.32 W/cm² or less is applied on the substrate per unit area.

9. The method of claim 1, wherein a frequency of the biasing high frequency power is equal to or lower than 2 MHz.

10. The method of claim 1, wherein an electron temperature of the plasma is equal to or less than 3 eV near the surface of the substrate.
